(19) United States
(12) Patent Application Publication
(10) Pub. No.: US 2018/0044793 A1
(43) Pub. Date: Feb. 15, 2018

(54) CONTAINER PLASMA TREATMENT PROCESS COMPRISING A THERMAL IMAGING PHASE

(71) Applicant: SIDEL PARTICIPATIONS, Octeville-sur-mer (FR)

(72) Inventor: Thierry DEAU, Octeville-sur-mer (FR)

(21) Appl. No.: 15/552,992

(22) PCT Filed: Feb. 10, 2016
(86) PCT No.: PCT/FR2016/050299

§ 371 Date: Aug. 23, 2017

(30) Foreign Application Priority Data
Feb. 23, 2015 (FR) 1551538

(51) Int. Cl. C23C 16/52; C23C 16/26; H01J 37/32; C23C 16/511; C23C 16/04

(52) U.S. Cl. CPC C23C 16/52; C23C 16/511; C23C 16/045; H01J 37/32394; C23C 16/26; H01J 37/32816

(57) ABSTRACT

Disclosed is a process for treating a container with plasma, for depositing a barrier layer on an internal face of the container. This process includes: after the plasma has been extinguished, obtaining a thermal image of the container; comparing the thermal image of the container with a reference thermal image stored in memory; and, if the thermal image of the container differs from the reference thermal image, modifying at least one of the following parameters: internal pressure, external pressure, precursor gas flow rate, microwave frequency, microwave power, duration of the treatment.

The invention relates to the treatment of containers made of polymer (such as PET) with plasma, and more specifically with plasma-assisted chemical vapor deposition, of a thin layer—typically (but not exclusively) hydrogenated amorphous carbon.

A hydrogenated amorphous carbon is a material that comprises carbon and hydrogen atoms that are commonly referred to by the formula a-C:H, which appears in the center of the ternary diagram of carbon-hydrogen equilibrium, as illustrated in particular in the Encyclopédie Ullmann de l'industrie chimique [Ullmann's Encyclopedia of Industrial Chemistry], 5^{th} Edition, Volume A26, p. 720.

The thin layers (or films) (with a thickness of between 0.050 μm and 0.200 μm) of hydrogenated amorphous carbon have the property of forming a barrier in particular to ultraviolet, to oxygen molecules, and to carbon dioxide. In the absence of such a barrier layer, the ultraviolet and the oxygen pass through the wall of the container and are likely to degrade the contents thereof, in particular beer or tea. As for the carbon dioxide of carbonated (so-called gaseous) beverages, there is also a tendency to escape by migration through the wall of the container.

Conventionally, and as described in particular in the European Patent EP 1 068 032 (Sidel Participations), to form a thin layer on the inner wall of a container, the first step is to insert the container into a chamber that is placed in a cavity that is conductive and transparent to the bulk of the microwave spectrum.

Then, both the container and the chamber are depressurized to obtain, on the one hand, in the container, a forced vacuum (of several μbar—remember that 1 μbar=10⁻⁶ bar) that is necessary for establishing plasma, and, on the other hand, in the chamber outside of the container, a mean vacuum (on the order of 30 mbar to 100 mbar) to prevent the container from contracting under the effect of the pressure difference on both sides of its wall.

Then, a precursor gas (typically a hydrocarbon in gaseous form, such as acetylene, C₂H₂) is injected into the container, and then an electromagnetic microwave field is generated in the cavity (and therefore in the chamber) to activate (and to support for a predetermined duration, generally on the order of several seconds) in the gas a plasma that separates the molecules from the gas and then recombines them into various radicals (in particular CH, CH₂, CH₃ in the case of a hydrocarbon such as acetylene), which are deposited in a thin layer on the inner wall of the container.

To perform the barrier function, not only is the layer to be sufficiently thick in the middle, but in addition, this thickness is to be fairly uniform, because any insufficiently covered area may offer a lesser barrier effect, to the detriment of the protection of the contents of the container.

Good homogeneity of the layer is difficult to achieve repeatedly because its distribution is sensitive to minor variations of multiple parameters (which include the shape of the container), and deviations that are imperceptible (and, moreover, detrimental to the quality of the containers) can occur from one cycle to the next.

Scrapping non-compliant containers, as the document CA 2 859 157 recommends, is only a stopgap, because it leads to a waste of time and energy without, however, correcting the defects that affect the production.

A first objective is to propose a solution that makes it possible to improve the homogeneity of the barrier layer.

A second objective is to improve the quality of the deposition in the treated containers.

A third objective is to ensure, as much as possible, the repetitiveness of the treatment cycle from one container to the next.

For this purpose, a method for treating a container with plasma for the deposition, on an inner face of the container, of a barrier layer is proposed, with this method comprising the operations that consist in:
Inserting the container into a chamber that is transparent to microwaves;
Creating in the container an inner partial vacuum of a predetermined value;
Creating in the chamber an outer partial vacuum of a predetermined value;
Injecting into the container a precursor gas according to a predetermined flow rate;
Subjecting the chamber to an electromagnetic wave of predetermined frequency in the microwave range and of predetermined power, in such a way as to energize a plasma in the precursor gas;
Maintaining the inner partial vacuum, the outer partial vacuum, the injection of precursor gas, and the electromagnetic wave to support the plasma for a predetermined treatment duration;
Extinguishing the plasma;
After the extinguishing of the plasma, producing a thermal image of the container;
Comparing the thermal image of the container to a reference thermal image that is stored in memory;
If the thermal image of the container differs from the reference thermal image, modifying at least one of the following parameters: inner partial vacuum, outer partial vacuum, precursor gas flow rate, frequency of microwaves, power of microwaves, duration of treatment.

This method makes it possible, by carrying out a thermal mapping of the container, to control indirectly the distribution of the deposited radicals, and therefore the thickness of the thin layer that is present on the wall of the container. The thickness of the layer can then, to a certain extent, be adjusted by modifying parameters, in particular to be more homogeneous.

Various additional characteristics can be provided, by themselves or in combination:
The generator is a magnetron, and the chamber is housed in a cavity that is equipped with movable plates made of an electrically conductive material, with the position of the plates being part in this case of the parameters that can be modified if the thermal image of the container differs from the reference thermal image;
With the inner partial vacuum being produced by means of a primary vacuum pump, the modification of the inner partial vacuum consists in modifying the flow rate of this primary vacuum pump;
With the outer partial vacuum being produced by means of a secondary vacuum pump, the modification of the outer partial vacuum consists in modifying the flow rate of this secondary vacuum pump;
With the precursor gas being injected into the container by means of an injector, the modification of the flow rate of the precursor gas consists in adjusting the opening of the injector;
The comparison is made by image correlation, in particular by local image correlation.

Other objects and advantages of the invention will become evident from the description of an embodiment, given below with reference to the accompanying drawings in which:

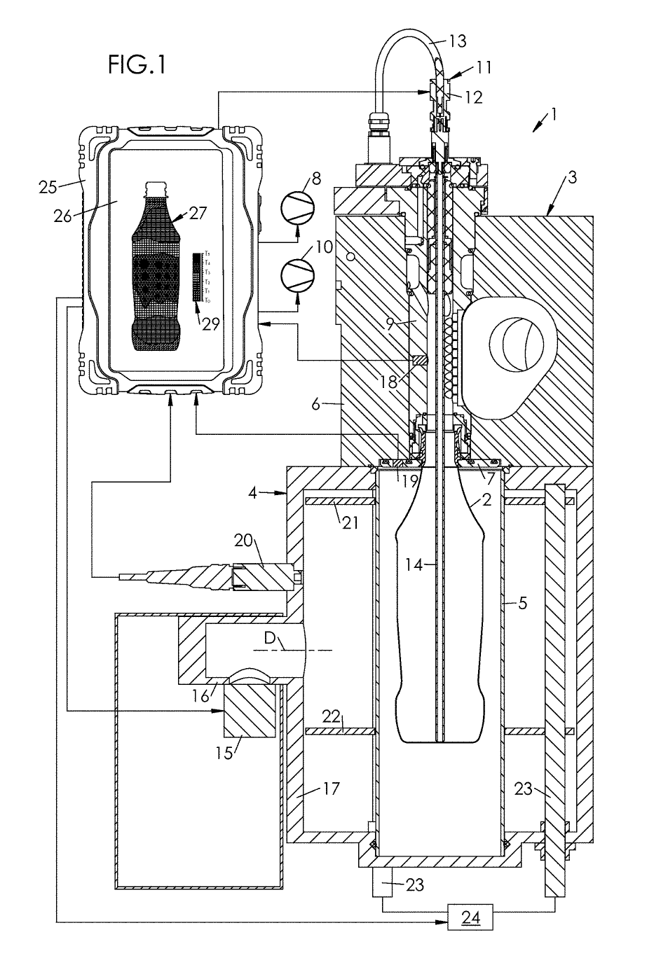

FIG. 1 is a partial cutaway view that illustrates an installation for the treatment of containers with plasma, to form a barrier layer on the inner wall of the containers;

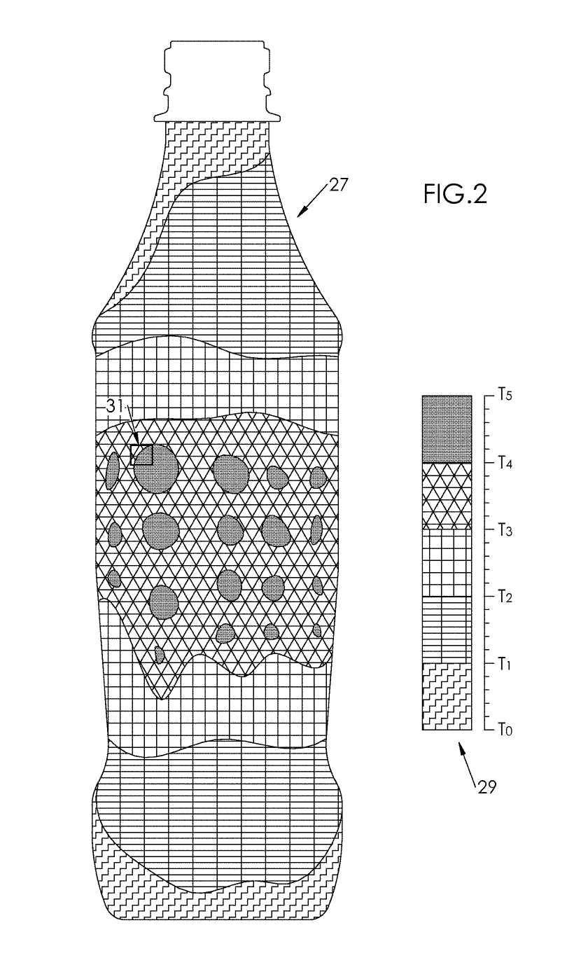

FIG. 2 is a thermal image of a container that is treated in an installation as shown in FIG. 1, accompanied, for reading the image, by a palette of colors corresponding to various temperature ranges;

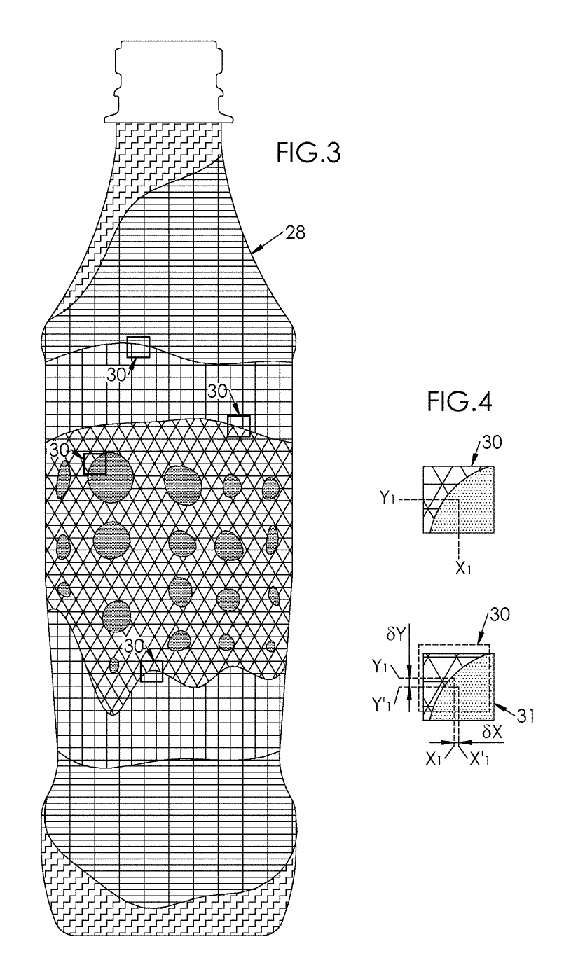

FIG. 3 is a thermal image of a reference container as ideally treated with plasma;

FIG. 4 is a diagram that illustrates an image correlation technique applied between the thermal image of FIG. 3 and the thermal image of FIG. 2.

Partially shown in FIG. 1 is an installation 1 for the treatment of containers 2 made of polymer with plasma-assisted chemical vapor deposition, on an inner wall of the containers 2, of a thin barrier layer.

Each container 2 that is to be treated (typically a bottle or a flask) presents its final shape; it was formed, for example, by blow molding or stretch blow molding from a preform. According to a particular embodiment, the container 2 is made of PET (polyethylene terephthalate).

The layer to be deposited can consist of hydrogenated amorphous carbon, which offers the advantage of forming a barrier to gases such as oxygen and carbon dioxide, to which PET by itself is relatively permeable. Other types of thin layers than those with a carbon base may be suitable for the same applications, in particular with a silicon oxide base or an aluminum oxide base.

The installation 1 comprises a large number of treatment stations 3, all similar, each configured for receiving and treating a single container 2 at the same time. The installation 1 also comprises a structure (preferably rotating, such as a carrousel) on which the treatment stations 3 are mounted, which are, for example, 24 in number, or else 48, in such a way as to make it possible to treat containers 2 at an industrial pace (on the order of several tens of thousands per hour).

Each treatment station 3 comprises an outer cavity 4 of an advantageously cylindrical shape, made of a conductive material, for example metal (typically steel or, preferably, aluminum, or an aluminum alloy), and sized to make it possible to set up within itself a stationary electromagnetic wave at a predetermined resonance frequency in the microwave range, and more specifically close to 2,450 MHz (or 2.45 GHz).

Each treatment station 3 also comprises a tubular chamber 5, mounted in a coaxial and fluidtight manner in the cavity 4 and made of a material that is transparent to a wide electromagnetic spectrum. More specifically, the chamber 5 is transparent at least to microwaves as well as to, preferably, the infrared range. According to an embodiment, the material in which the chamber 5 is made is quartz.

According to a particular embodiment that is illustrated in FIG. 1, the chamber 5 is, at a lower end, interlocked in a fluidtight manner in an additional area that is formed in a lower wall of the cavity 4.

At an upper end, the chamber 5 is closed in a fluidtight manner by a removable cover 6 that makes it possible to insert a container 2 into the chamber 5 to allow its treatment and to remove it therefrom after the end of the treatment.

As is seen in FIG. 1, the treatment station 3 is equipped with a support 7 (here of the fork type) that works with a neck of the container 2 to ensure the suspension of the former in the chamber 5, and various joints that ensure the sealing of the inner volume of the container 2 relative to the chamber 5.

The following are thus separated in a fluidtight manner:
The interior of the container 2,
The interior of the chamber 5 with the exterior of the container 2,
The interior of the cavity with the exterior of the chamber 5.

For more detail on carrying out the sealing, one skilled in the art can refer to the description of the patent application US 2010/0007100.

The treatment station 3 comprises:
A primary vacuum circuit comprising a primary vacuum pump 8 that makes it possible to create a forced vacuum (on the order of several microbars) in the container 2, via a nozzle 9 that is formed in the cover 6 and that empties into the container 2 (when the former is present), and
A secondary vacuum circuit that comprises a secondary vacuum pump 10 that makes it possible to create a mean vacuum (on the order of several millibars) in the chamber 5 with the exterior of the container 2, to prevent the former from contracting under the effect of the pressure difference on both sides of its wall.

The treatment station 3 also comprises an injection device 11, in the chamber 5, of a precursor gas such as acetylene (of formula C₂H₂). As is seen in FIG. 1, this device 11 comprises an injector 12 that is connected, via a hose 13, to a source (not shown) of precursor gas, and an injection tube 14 that is connected to the injector 12 to direct the precursor gas into the container 2. The injector 12 has an adjustable opening, in such a way as to make possible a variation of the precursor gas flow rate in the container 2.

For more detail relating to the structure of the cavity 4, one skilled in the art will be able to refer to the description of the patent application US 2010/0206232.

The treatment station 3 also comprises a generator 15 of electromagnetic waves in the microwave range, and more specifically here, in the vicinity of 2,450 MHz (or 2.45 GHz). According to an embodiment that is illustrated in FIG. 1, the generator 15 is a magnetron, and it is coupled to the cavity 4 by means of a wave guide 16 that empties into the cavity 4 by a window made through a side wall 17 of the cavity 4 by forming a primary direction D for propagation of microwaves.

The treatment station 3 also comprises a primary pressure sensor 18 that empties into the nozzle 8 to measure the pressure therein (and therefore the pressure prevailing in the container 2, which is in communication with the nozzle 8). The treatment station 3 also comprises a secondary pressure sensor 19 that empties into the inner volume delimited by the chamber 5 to measure the pressure therein. In the illustrated example, the secondary pressure sensor 19 is mounted under the cover 6 and extends through a slot made in the support 7.

The installation comprises at least one thermal camera 20 that is arranged to produce a thermal image of the container 2. Such an image, made in the infrared range of the electromagnetic spectrum, makes it possible to map the container 2 in terms of temperature.

The camera 20 is, for example, the model A315 marketed by the FLIR Company, which makes it possible to produce images in the thermal range from −20° C. to 120° C. with a resolution of 320×240 pixels.

According to a particular embodiment (not illustrated), the camera 20 is common to multiple (and, for example, to all) treatment stations 3, by being positioned in a stationary manner facing a discharge point with which the containers are evacuated from cavities 4 after having been treated. In this case, the thermal camera 20 points toward each container 2 at the outlet of the cavity 4.

According to another embodiment that corresponds to the illustration of FIG. 1, each treatment station 3 integrates a thermal camera 20.

Thus, in the illustrated example, the thermal camera 20 is mounted on the side wall 17 of the cavity 4 facing the area where the container 2 is found. With the chamber 5 being transparent to the wavelengths of the infrared range, it does not form an obstacle to the radiation obtained from the container 2, which can therefore be collected without attenuation by the thermal camera 19.

With the container 2 being a solid of revolution, several cameras 20 can be provided, distributed around the container, for example at 120°. However, at least one camera 20 (the one shown in FIG. 1) is placed perpendicular to the waveguide 16 and points in the direction D of propagation of the waves.

As is seen, furthermore, in FIG. 1, the forming station 3 comprises a pair of superposed annular plates, namely an upper plate 21 and a lower plate 22 that are placed in the cavity 4 around the chamber 5 by being offset vertically in such a way as to be located on both sides of the waveguide 16. The plates 21, 22 are made of an electrically conductive material (for example, steel or aluminum) and have as their function to confine the electromagnetic field to the area where the container 2 is located. The plates 21, 22 are attached to rods 23 that extend vertically through the cavity 4 and make possible an adjustment of the position of the plates 21, 22 in such a way as to make possible the treatment of containers of varied sizes. For this purpose, at least one of the rods 23 can be threaded by being helically meshed with a tapping made in at least one of the plates 21, 22. The rotation of the threaded rod 23 thus makes it possible to adjust the vertical position of the plate(s) 21, 22.

More accurately, it is preferable to be able to adjust independently the vertical position of the upper plate 21 and that of the lower plate 22. For this purpose, one of the rods 23 is, for example, helically meshed with the upper plate 21 while another rod 23 is helically meshed with the lower plate 22. A power plant 24 makes it possible to make the rod(s) 23 rotate to adjust the vertical position of each plate 21, 22.

In the illustrated example, where the treatment station 3 integrates one (or more) thermal camera(s) 20, the rods 23 are positioned so as not to be found between the thermal camera(s) 20 and the container 2, in such a way as to avoid inducing shadow on the thermal image of the former. According to an embodiment that is illustrated in FIG. 1, the rods 23 are three in number, distributed at 120° around the chamber 5, with one of these rods 23 being diametrically opposite to the thermal camera 20. As a variant, the rods 23 are two in number and are diametrically opposite in a plane that is perpendicular to the direction D of propagation.

The installation 1 further comprises a computerized monitoring unit 25 (in the form of a programmable robot, a computer, or more simply a processor), which can be dedicated to the treatment station 3 or which can be common to all of the former. The monitoring unit 25 is advantageously equipped with a graphic interface 26 (here in the form of a flat screen, optionally a touch screen), making it possible to display information, and in particular a thermal image 27 of the container 2 produced by means of the camera 20.

The monitoring unit 25 is connected:
To the primary vacuum pump 8 whose flow rate it can adjust;
To the secondary vacuum pump 10, also whose flow rate it can adjust;
To the primary pressure sensor 18 that communicates with the monitoring unit 25 the pressure measurements in the nozzle 9 (and therefore in the container 2);
To the secondary pressure sensor 19 that communicates to the monitoring unit 25 the pressure measurements in the chamber 5;
To the injector 12 whose monitoring unit 25 can thus adjust the flow rate by adjusting its opening;
To the (or each) thermal camera 20 that communicates to the unit 25 the thermal measurements taken on the container 2;
To the generator 15 whose monitoring unit 25 can adjust the power as well as, if necessary, the frequency of the microwaves when this frequency can be adjusted;
To the power plant 24 for adjusting, if necessary, the vertical position of the plates 21, 22 and thus for matching the cavity 4 to the generator 15.

The connections of the monitoring unit 25 to these various components can be wired (for example, according to the IEEE 802.3 “Ethernet” protocol) or, in some cases, wireless (for example, according to the IEEE 802.15 “BlueTooth®” protocol). These connections are shown in diagram form in FIG. 1 by lines. The arrows indicate for each the direction of circulation of the information.

The treatment of a container 2 is carried out in the following manner.

The container 2 is, by means of the support 7, placed and suspended in the chamber 5. The sealing is carried out, on the one hand, in the area of the neck of the container 2 between the interior and the exterior of the former (i.e., in the chamber 5), and, on the other hand, between the chamber 5 and the cavity 4.

An inner partial vacuum is produced in the container 2 by means of the primary vacuum pump 8 that is controlled by the monitoring unit 25, with the residual pressure being several μbar. In other words, a forced vacuum is produced in the container 2. The expression “inner partial vacuum” is used to qualify the difference (negative) between the residual pressure prevailing in the container 2 and the atmospheric pressure.

A partial vacuum is also produced in the chamber 5 on the exterior of the container 2 by means of the secondary vacuum pump 10 controlled by the monitoring unit 25, in such a way as to avoid a crushing of the former under the pressure difference on both sides of its side wall. The expression “outer partial vacuum” is used to qualify the difference (also negative) between the pressure that prevails in the chamber 5 and the atmospheric pressure.

The precursor gas is injected into the container 2 by means of the injector 12 that is controlled by the monitoring unit 25. The vacuum pump 8 is kept open to make it possible to renew the precursor gas.

The generator 15 is activated by the monitoring unit 25. The propagation of the microwaves in the cavity 4 produces a superposition of incident and reflected waves and the setting-up in the cavity 4 of, for certain frequencies, a stationary microwave electric field, whose spatial distribution is not uniform and that has in the area of the container 2, owing to a particular positioning of the plates 21, 22, a local concentration of energy that makes it possible to trigger a plasma in the precursor gas.

The plasma results from the molecular breakdown of the precursor gas by the microwave energy that is concentrated in the core of the container 2. The molecular breakdown of the precursor gas (in this case, acetylene) produces a soup of varied volatile radicals such as CₓH_{y}, where x and y are real numbers with x≧0 and y≧0, at least one part of which is ionic.

A portion of these CₓH_{y} radicals are deposited on the wall of the container 2 (thus contributing to the generation of a thin layer of hydrogenated amorphous carbon) that they heat by transferring thereto a portion of their caloric energy.

The inner partial vacuum, the outer partial vacuum, the injection of precursor gas, and the electromagnetic wave are maintained, to support the plasma, during a predetermined treatment duration of between 1 s and 5 s.

The spatial distribution of the radicals in the inner volume delimited by the container 2 is non-uniform, because the spatial distribution of the energy of the microwaves is itself non-uniform, due to the presence in the cavity 4 of objects that affect the microwaves (in particular the tube 14 that forms an antenna and the container 2 that forms a dielectric).

The result is that the barrier layer that is formed in the interior on the wall of the container 2 by the deposition of radicals obtained from the plasma does not have a perfect homogeneity, its thickness having local variations.

It is undoubtedly illusory to attempt to obtain a barrier layer that has a perfect homogeneity, i.e., a constant thickness over the entire inner surface of the wall of the container 2. Certain irregularities in the deposition, however, can be leveled out by adjusting various parameters of the method (pressure in the container 2, pressure in the chamber 5, flow rate of precursor gas, emission power of the generator 15, if necessary emission frequency of the generator 15, treatment duration, position of the plates 21, 22).

If it is difficult to physically measure the thickness of the deposition other than by destructive tests, it is by contrast possible to measure it indirectly by means of a thermal image of the treated container 2, because, as we have seen, the wall of the container 2 is heated by the deposition of radicals, and the heat transferred to the wall of the container 2 is proportional to the thickness of the deposition. Of course, thermal conduction ensures that the temperature variations that can be detected on the wall of the container 2 tend to smooth out as, once the treatment is finished, the container 2 cools. This is why it is preferable to initiate a thermal mapping of the container 2 immediately after the end of the treatment.

If the thermal camera(s) 20 is (are) integrated in the forming station 3, the thermal mapping of the container 2 can be carried out before the former is evacuated from the cavity 4. The illustrated mounting makes it possible to proceed in this direction.

If the thermal camera 20 is stationary by being placed at the evacuation point of the containers 2 from their respective cavities 4, the thermal mapping of each container 2 is carried out after the evacuation of the container 2 from its cavity 4. With several tenths of seconds at the very most separating the end of treatment from the evacuation of the container 2 from the cavity 4, the result is not appreciably different from an internal measurement in the cavity 4.

The treatment is declared to be finished as soon as the plasma is extinguished (either the generator 15 has been turned off or the injection of the precursor gas has been stopped). The expression “immediately after the end of the treatment” means that the thermal image of the container is produced at the very moment the plasma is extinguished, or at most several fractions of seconds (at most one second) after this extinguishing.

A thermal mapping of the container 2 is, however, useless if there is no reference with which to compare it. This is why at least one reference thermal image 28 of an ideal model of a treated container is stored in memory in the monitoring unit 25. According to an embodiment, multiple reference thermal images 28, made according to multiple views, are stored in memory in the monitoring unit 25 to make possible a comparison with thermal images 27 made according to the same views.

FIG. 2 shows a thermal image 27 of a container 2 whose treatment was just completed. Since the infrared range is invisible to the eye, the image 27 is re-treated with false colors so that it can be read and interpreted in the visible range. A legend 29 makes it possible to read and interpret the image 27. The colors are arbitrary; for the sake of clarity, FIG. 2 shows various temperature ranges [T₁; T₁₊₁] (where i is a positive integer or zero, with the temperatures increasing according to the increasing value of the index i) with different patterns. Five ranges are illustrated, showing increasing temperature values:

[T₀; T₁] with a zigzag pattern;

[T₁; T₂] with a rectangular grid pattern;

[T₂; T₃] with a square grid pattern;

[T₃; T₄] with a triangular grid pattern;

[T₄; T₅] with a dot pattern.

As the thermal image 27 of the container 2 shows, the temperature is relatively higher in a median zone of the former and decreases when it is moved away from the former to reach minimal values in the vicinity of the neck and the bottom of the container 2.

It is desired to be able to modify the parameters of the treatment if the former is declared to be defective (which is reflected by the fact that the image 27 of the container 2 differs from the reference image 28).

The comparison of the images 27, 28 can be carried out by image correlation (by means of an algorithm programmed into the monitoring unit 25).

Comparing the images 27, 28 in their entirety (by a so-called overall image correlation) is feasible but requires a great deal of computing power without necessarily being effective, while being difficult to interpret.

This is why it is preferable to initiate local image correlation by selecting one or more restricted zones or reference thumbnail(s) 30, presumed to bear witness to that (them) alone of the distribution of the barrier layer. In the example that is illustrated in FIG. 3, four reference thumbnails 30 are shown, with a rectangular contour, one of which was selected in FIG. 4 to illustrate an image correlation technique that can be applied in this method.

With the reference image 28 being two-dimensional, respectively the positions following a horizontal axis and a vertical axis from the geometric center of a reference thumbnail 30 are referenced by the coordinate Xₙ (abscissa) and the coordinate Yₙ (ordinate), where n is an integer that represents the index of the reference thumbnail 30. In FIG. 4, for the sake of convenience, the index n=1 is assigned to the reference thumbnail 30 that is shown, This reference thumbnail 30 corresponds to the leftmost thumbnail 30 in the reference image 28 of FIG. 3.

To carry out the image correlation applied to the reference thumbnail 30, the monitoring unit 25 searches in the thermal image 27, in the vicinity of the point of coordinates X₁, Y₁, for a thumbnail of the same size, similar to the reference thumbnail 30 and whose deviation from the former is minimal. This thumbnail, which is referenced under the number 31, is called “correlated thumbnail.” Its geometric center is referenced by the coordinates X′₁, Y′₁.

By denoting as δX the deviation between X₁ and X′₁, and as δY the deviation between Y₁ and Y′₁, the thumbnail 31 correlated with the reference thumbnail 30 is that which minimizes the distance E between the centers of the thumbnails 29, 30

(E=\sqrt{δX²δY²}).

After having evaluated this distance E, the monitoring unit 25 compares it to a reference value E₀ that is stored in memory.

If, for each correlated thumbnail 31, the distance E is less than the reference value E₀, then the correlated thumbnail 31 is declared to be merged with the reference thumbnail 29 and, more generally, the thermal image 27 is declared to be merged with the reference image 28. It is concluded from this that the deposition of the barrier layer is in keeping with the ideal, and the parameters of the method are preserved for the next cycle (or a next series of cycles).

If, in contrast, for at least one correlated thumbnail 31, the distance E is greater than the reference value E₀, then the correlated thumbnail 31 is declared to differ from the reference image 28.

In this case, the monitoring unit 25 controls a modification of at least one of the parameters of the method, from among:
The inner partial vacuum (to be maximized, in absolute value, to obtain better homogeneity),
The outer partial vacuum (with an equal inner partial vacuum, an outer partial vacuum that is too small in absolute value can lead to a crushing of the container 2 but brings about a natural ventilation of the container 2 that prevents the risk of burning; in contrast, an outer partial vacuum that is too high in absolute value limits the cooling and consequently increases the risk of burning of the container 2),
The flow rate of precursor gas (a flow rate that is too low does not make it possible to obtain a sufficient layer thickness; a flow rate that is too high creates, in contrast, hot points that can cause burns on the wall of the container 2),
The emission power of the generator 15 (a power that is too low increases the temperature deviations; in contrast, a power that is too high also creates hot points that can cause burns on the wall of the container 2);
The duration of the plasma treatment (i.e., the time interval between the triggering and the extinguishing of the plasma; a treatment duration that is too high increases the risk of burning; a duration that is too short can lead to a layer thickness that is too small);
If necessary, the position of the plates 21, 22;
If necessary, the emission frequency of the generator 15.

The cycle is repeated with another container 2, and the parameter(s) is (are) modified as long as the correlation provides a negative result, i.e., the thermal image 27 is declared not to be merged with the reference image 28.

The method that was just described makes it possible, firstly, to improve the homogeneity of the barrier layer, and therefore the quality of the treated containers.

It makes it possible, secondly, to increase the repetitiveness of the treatment cycle from one container 2 to the next by avoiding the deviations, owing to the thermal images that can be produced in each cycle (i.e., for each container 2), or periodically (for example, every ten cycles).

1. Method for treating a container (2) with plasma for the deposition, on an inner face of the container (2), of a barrier layer, with this method comprising the operations that consist in:
Inserting the container (2) into a chamber (5) that is transparent to microwaves;
Creating in the container (2) an inner partial vacuum of a predetermined value;
Creating in the chamber (5) an outer partial vacuum of a predetermined value;
Injecting into the container (2) a precursor gas according to a predetermined flow rate;
Subjecting the chamber (5) to an electromagnetic wave of predetermined frequency in the microwave range and of predetermined power, in such a way as to energize a plasma in the precursor gas;
Maintaining the inner partial vacuum, the outer partial vacuum, the injection of precursor gas, and the electromagnetic wave to support the plasma for a predetermined treatment duration;
Extinguishing the plasma;
the method further comprising:
After the extinguishing of the plasma, producing a thermal image (27) of the container (2);
Comparing the thermal image (27) of the container to a reference thermal image (28) that is stored in memory;
If the thermal image (27) of the container (2) differs from the reference thermal image (28), modifying at least one of the following parameters: inner partial vacuum, outer partial vacuum, precursor gas flow rate, frequency of microwaves, power of microwaves, duration of treatment.

2. Method according to claim 1, in which, with the inner partial vacuum being produced by means of a primary vacuum pump (8), the modification of the inner partial vacuum consists in modifying the flow rate of this primary vacuum pump (8).

3. Method according to claim 1, wherein, with the generator (15) being a magnetron and the chamber (5) being housed in a cavity (4) that is equipped with movable plates (21, 22) made of an electrically conductive material, the position of the plates is part of the parameters that can be modified if the thermal image (27) of the container (2) differs from the reference thermal image (28).

4. Method according to claim 1, in which with the outer partial vacuum being produced by means of a secondary vacuum pump (10), the modification of the outer partial vacuum consists in modifying the flow rate of this secondary vacuum pump (10).

5. Method according to claim 1, in which, with the precursor gas being injected into the container (2) by means of an injector (12), the modification of the flow rate of precursor gas consists in adjusting the opening of the injector (12).

6. Method according to claim 1, in which the comparison is made by image correlation.

7. Method according to claim 6, in which the comparison is made by local image correlation.

8. Installation for the treatment of a container (2) with plasma for the deposition, on an inner face of the container (2), of a barrier layer, with this installation comprising:
A chamber (5) that is transparent to microwaves, able to receive the container (2) that is to be treated;
A primary vacuum circuit that can create in the container (2) an inner partial vacuum of a predetermined value;
A secondary vacuum circuit that can create in the chamber (5) an outer partial vacuum of a predetermined value;
A device (11) for injection of a precursor gas into the container (2) according to a predetermined flow rate;
A generator (15) of electromagnetic waves in the range of microwaves at a predetermined frequency and of predetermined power, suitable for energizing a plasma in the precursor gas;
further comprising:
A thermal camera (20) that is suitable for producing a thermal image (27) of the container (2);
A monitoring unit (24) that is programmed for:
Comparing the thermal image (27) of the container to a reference thermal image (28) that is stored in memory;
If the thermal image (27) of the container (2) differs from the reference thermal image (28), modifying at least one of the following parameters: inner partial vacuum, outer partial vacuum, precursor gas flow rate, frequency of microwaves, power of microwaves, duration of treatment.

9. Method according to claim 2, in which with the outer partial vacuum being produced by means of a secondary vacuum pump (10), the modification of the outer partial vacuum consists in modifying the flow rate of this secondary vacuum pump (10).

10. Method according to claim 2, in which, with the precursor gas being injected into the container (2) by means of an injector (12), the modification of the flow rate of precursor gas consists in adjusting the opening of the injector (12).

11. Method according to claim 3, in which, with the precursor gas being injected into the container (2) by means of an injector (12), the modification of the flow rate of precursor gas consists in adjusting the opening of the injector (12).

12. Method according to claim 4, in which, with the precursor gas being injected into the container (2) by means of an injector (12), the modification of the flow rate of precursor gas consists in adjusting the opening of the injector (12).

13. Method according to claim 2, in which the comparison is made by image correlation.

14. Method according to claim 3, in which the comparison is made by image correlation.

15. Method according to claim 4, in which the comparison is made by image correlation.

16. Method according to claim 5, in which the comparison is made by image correlation.

17. Method according to claim 9, in which, with the precursor gas being injected into the container (2) by means of an injector (12), the modification of the flow rate of precursor gas consists in adjusting the opening of the injector (12).

18. Method according to claim 9, in which the comparison is made by image correlation.

19. Method according to claim 10, in which the comparison is made by image correlation.

20. Method according to claim 11, in which the comparison is made by image correlation.
